(19) United States
(12) Patent Application Publication
(10) Pub. No.: US 2025/0321306 A1
(43) Pub. Date: Oct. 16, 2025

(54) Magnetic Resonance Imaging Using Sequence Segment Correlation

(71) Applicant: Siemens Healthineers AG, Forchheim (DE)

(72) Inventor: Mario Zeller, Erlangen (DE)

(73) Assignee: Siemens Healthineers AG, Forchheim (DE)

(21) Appl. No.: 19/176,257

(22) Filed: Apr. 11, 2025

(30) Foreign Application Priority Data
Apr. 11, 2024 (DE) 10 2024 203 342.1

(51) Int. Cl. G01R 33/56; G01R 33/561; G01R 33/565

(52) U.S. Cl. CPC G01R 33/5608; G01R 33/5616; G01R 33/56518

(57) ABSTRACT

Method for operating an MR apparatus in an acquisition process in accordance with an acquisition protocol including, in at least one repetition, sequence segments of an MR sequence, wherein each sequence segment includes a preparation module and a readout module, and each readout module includes readout submodules, each readout submodule including respective RF pulses followed by respective readout time periods during which MR data is acquired. The method includes: acquiring navigator dataset of the sequence segment for each readout module using a navigator submodule included in the readout module; determining correlation information for each sequence segment by comparing the navigator dataset of the sequence segment with a navigator dataset of a further sequence segment; and evaluating the correlation information to select sequence segments whose MR data is discarded, and/or to assign a weighting to the MR data of some of the sequence segments prior to reconstruction of an MR image.

### TECHNICAL FIELD

The disclosure relates to a computer-implemented method for operating a magnetic resonance apparatus in an acquisition process in accordance with an acquisition protocol, which comprises in at least one repetition a plurality of sequence segments of a magnetic resonance sequence, wherein each sequence segment comprises a preparation module and a readout module, and each readout module comprises a plurality of readout submodules, in which, respective radiofrequency pulses precede respective readout time periods for acquiring magnetic resonance data. The disclosure also relates to a magnetic resonance apparatus, to a computer program, and to an electronically readable data storage medium.

### BACKGROUND

Magnetic resonance imaging is now a frequently used diagnostic and monitoring tool in medical applications. The prolonged acquisition time length of usual acquisition protocols for magnetic resonance data means that movement is a key issue in improving the image quality, because movements during the acquisition time length, even when corrected, can lead to a loss of image quality and hence also of usability of the magnetic resonance data and magnetic resonance images/image datasets reconstructed therefrom. Movement during the acquisition of a patient here relates both to periodic movement processes, for instance, respiration and heartbeat, in the living object under examination and to other, voluntary and involuntary, externally and internally initiated movement actions of the acquisition region.

Avoiding or taking account of movement proves particularly relevant in TSE sequences (turbo spin echo sequences, also known as RARE sequences or FSE sequences). In a TSE sequence, a radiofrequency excitation pulse in a preparation module is followed by what is known as an echo train in a readout module, in which, in a plurality of readout submodules, respective readout time periods adjoin respective radiofrequency refocusing pulses, which readout time periods all capitalize on the same radiofrequency excitation pulse. This results in acquisition time lengths of several minutes, given a plurality of echo trains. Nonetheless, the merits of the TSE sequence mean that it is deployed as the “workhorse” of medical imaging. Movement is similarly relevant also in other sequence types of similar design, for instance in diffusion imaging with gradient echo (GRE) readout, in which a preparation module containing diffusion gradients is followed by a readout module, in which in respective readout submodules of a readout module, a readout time period follows a radiofrequency excitation pulse.

In order to be able to work with less magnetic resonance data and hence shorten the acquisition time length, trained reconstruction algorithms have been proposed, which use as input data directly the, in particular undersampled, magnetic resonance data in k-space, and output magnetic resonance images in image space, i.e., the spatial domain. An example of such functions is those that use unrolled neural network architectures. For example, an article by Florian Knoll, “Deep-Learning Methods for Parallel Magnetic Resonance Imaging Reconstruction: A Survey of the Current Approaches, Trends, and Issues”, IEEE Signal Process Mag. 37 (2020), pages 128 to 140 contains a summary of deep-learning approaches in magnetic resonance reconstruction.

Such trained reconstruction algorithms allow a significant reduction in the acquisition time length with high acceleration factors and yet better image quality compared with conventional reconstruction methods such as GRAPPA (Generalized autocalibrating partially parallel acquisitions, cf. the article of the same name by Mark A. Griswald in Magn. Reson. Med. 47 (2002), pages 1202-1210). The noise-suppressing action of the trained function, in particular of the comprised neural network, however, means that image artifacts caused by movement are also reconstructed more visibly than with conventional reconstruction methods in which such artifacts are often lost in the noise. In principle, however, these reconstruction approaches, for instance, GRAPPA, are also affected by the motion effects.

Various approaches have already been proposed in the prior art in order to reduce motion artifacts. For example, SAMER (Scout accelerated motion estimation and reduction) is known, cf. D. Polak et al., MRM 87 (2022), pages 163-178. In this approach, a reference dataset is acquired in a short reference scan at the start of the acquisition process. In each sequence segment, in particular echo train, several low-resolution navigator echoes are then acquired. Subsequently, in an optimization process in the image reconstruction, the navigator echoes are fitted to the reference dataset in order to derive therefrom motion correction parameters, which are used for suitable correction of the magnetic resonance data of the respective readout submodules. The process cannot currently be combined with deep-learning reconstructions, i.e., with the use of trained reconstruction functions, and therefore offers only limited acceleration opportunities. In addition, it cannot be used to compensate for pulsating motion effects (pulsation effects).

### SUMMARY

Therefore, an object of the disclosure is to define a method for obtaining magnetic resonance data that is improved in terms of motion artifacts caused by both pulsating and other movements.

This object is achieved according to the disclosure by a computer-implemented method, a magnetic resonance apparatus, a computer program, and an electronically readable data storage medium as claimed in the independent claims. The dependent claims contain advantageous developments.

In a method of the type mentioned in the introduction, it is provided according to the disclosure that:
in each readout module, at least one navigator submodule is used to acquire navigator data of the sequence segment;
for each sequence segment, correlation information is determined by comparing the navigator dataset of the sequence segment with at least one navigator dataset of a further sequence segment; and
the correlation information is evaluated in order to select sequence segments, the magnetic resonance data of which is discarded, and/or to assign a weighting to the magnetic resonance data of at least some of the sequence segments before reconstruction of a magnetic resonance image.

Two fundamental approaches are conceivable here. While one option is to weight the magnetic resonance data of the sequence segments as a whole, for instance depending on the magnitude of the movement, which is described by the deviation in the comparison, another advantageous variant provides that when at least one deviation condition, which evaluates the correlation information, is satisfied for one of the sequence segments, the magnetic resonance data of the sequence segment is discarded or, in a subsequent reconstruction of a magnetic resonance image, is given less weight than the magnetic resonance data of sequence segments that do not satisfy the deviation condition.

The deviation condition, or in general, the existence of a deviation described by the correlation information, indicates, based on the difference in the navigator dataset of an assessed sequence segment from at least one navigator dataset of another sequence segment, that the assessed sequence segment might be affected by movement. Movement relating to a patient as the object under examination can comprise here not only periodic body movement such as respiration and heartbeat but also other, voluntary or involuntary, in particular macroscopic, movements. The term pulsation is often used here, in particular, with regard to the heartbeat. Thus, the proposed method relates to increasing the image quality of magnetic resonance images in terms of any movements in the acquisition region by identifying and discarding, or at least weighting less for the reconstruction, magnetic resonance data affected by movement in order to avoid motion artifacts.

Discarding shall be understood to mean here that the magnetic resonance data of the sequence segment is no longer included in a subsequent reconstruction. This means that at least one magnetic resonance image is reconstructed from the remaining magnetic resonance data so that a considerable reduction in the number of movement-related artifacts is possible as a result of the removal of movement-polluted magnetic resonance data. This can also be achieved with lower weighting of said magnetic resonance data, in which case, while it is possible to maintain a certain sampling density, the movement-affected magnetic resonance data has less influence on the magnetic resonance image. For example, this can specifically counteract the amplification effect in trained reconstruction functions that was mentioned in the introduction. An advantage of the procedure described here when deployed after the acquisition process is that it can be implemented easily before the reconstruction, because only a simple step for identifying movement-affected sequence segments and discarding or specifying the weighting has to be inserted before the actual image reconstruction, but the reconstruction itself does not have to be modified.

It can be provided particularly advantageously to use for the reconstruction a, in particular trained, reconstruction function, which compensates for missing magnetic resonance data, in particular a reconstruction function based on an unrolled neural network architecture, which receives as input data magnetic resonance data in k-space, and delivers as output data at least one magnetic resonance image in image space (spatial domain).

The combination of identifying and discarding movement-affected magnetic resonance data with trained reconstruction functions, in particular, k-space-to-image-space based unrolled neural networks (for example, known as “Deep Resolve Boost”), is particularly advantageous because these trained reconstruction functions are resilient to slight changes in the sampling pattern. This means that high-quality reconstruction is still possible despite magnetic resonance data potentially being missing as a result of the discarding. In other words, the network architecture of the trained reconstruction function does not necessarily need regularly sampled magnetic resonance data as input data. Therefore, with the method described here, movement-affected sequence segments, in particular echo trains, can be detected and discarded before the reconstruction.

In an advantageous development, however, it is also possible to introduce weighting into the input data of the reconstruction function. For example, it can preferably be provided that the trained reconstruction function uses, in addition to the magnetic resonance data as input data also a sampling mask, which describes the distribution of the sampled sample points in the sampled k-space, wherein
for magnetic resonance data to be discarded, the corresponding sample points are labeled as not sampled and/or
for magnetic resonance data to be weighted, the weighting is entered in the sampling mask at the corresponding sample points, wherein the reconstruction function is designed to use the weighting in the reconstruction and/or in a check of the consistency between the reconstruction result and the magnetic resonance data.

In particular, a binary sampling mask can be assumed here, in which sampled points in k-space are assigned a one, non-sampled points a zero. In the case of discarded magnetic resonance data, the corresponding portions of k-space are labeled simply with zero in the mask. In the case of a weighting, however, values between zero and one can be introduced particularly advantageously. Of course, this can also be applied to sampling masks that work with other base values and/or even already use a weighting. Thus, the sampling mask specifies how much weight the magnetic resonance data is meant to receive in the reconstruction or in the data consistency check.

It can be particularly advantageous here to employ the weighting solely or mainly for the consistency check. Then, the magnetic resonance data contributes fully to the reconstruction, i.e., it maintains the sampling base but is given less consideration in the consistency check so that a considerable reduction in movement-based artifacts is still possible.

Of course, a combination with other reconstruction methods such as GRAPPA, for example, is also conceivable in principle, however. In this case, discarded magnetic resonance data in k-space, for example, missing k-space lines, must be reconstructed additionally, which sometimes can necessitate calculating additional reconstruction kernels, for example, GRAPPA kernels. It is also conceivable to implement a weighting mechanism.

In general, it can be said that the weighting, in particular of the magnetic resonance data to be weighted less, is selected according to a magnitude of the deviation of the navigator data of a sequence segment from that of the at least one other sequence segment, in particular the magnitude of the infringement of the deviation condition, and/or according to its location in the sampled k-space. In exemplary aspects, the magnitude of the deviation can be described directly by the correlation information, for instance, a correlation value. In particular with regard to the former aspect of the location in k-space, it should be mentioned that in general it is also conceivable to select different weightings within a sequence segment, for instance to select a higher weighting for magnetic resonance data relating to sample points lying closer to the center of k-space than for magnetic resonance data relating to sample points lying farther away from the center of k-space. For example, the weighting can be made on the basis of k-space lines (or k-space trajectory segments). It can thus be stated that advantageously, central regions of sampled k-space should make a greater contribution than the edge of sampled k-space because the majority of the signal is present in the central regions.

Alternatively or additionally, the weighting can depend on the magnitude of the deviation, in particular, the infringement of the deviation condition, which, in fact, describes the magnitude of the relative detected movement. In the example of the sampling mask discussed above, which uses values of zero to one, the weighting can lie close to zero given strong movement, close to one given just slight movement. For example, for the sequence segments that satisfy the deviation condition, a weighting can be chosen that decreases linearly, or by some other function, with the magnitude of the infringement of the deviation condition.

It is also conceivable, however, if no deviation condition is meant to be used, that in order to define the weighting, a magnitude of the deviation is determined for each sequence segment, wherein the weighting decreases, in particular linearly, with the magnitude of the deviation. In other words, all the sequence segments can be sorted according to the magnitude of the deviation, i.e., in particular movement magnitude, and all the sequence segments are assigned a weighting that decreases, in particular linearly, according to movement magnitude.

A further general advantage of the method according to the disclosure is that it is also possible to identify and take into account short-term influences in the timescale of an individual sequence segment, for instance, echo train, for a single slice. Thus, in particular, a complete repetition, i.e., a TR period, does not have to be discarded or weighted less if a movement effect extends only over a few hundred milliseconds of a sequence segment.

The method can be employed particularly advantageously for turbo spin echo sequences (TSE sequences). It can thus be provided that the magnetic resonance sequence is a turbo spin echo sequence, in which the radiofrequency pulses of the readout submodules are refocusing pulses. For TSE sequences, in the preparation module, a radiofrequency excitation pulse is output, which is used for a plurality of readout time periods in the echo train in respective TSE submodules. In addition, a radiofrequency refocusing pulse is output before each readout time period.

It is specifically proposed to identify movement-affected sequence segments on the basis of an additional navigator echo per sequence segment. Thus, navigator data is acquired in a corresponding navigator submodule so that a navigator dataset is available for each navigator submodule and, hence, for each sequence segment. This can be correlated, i.e., compared, with other navigator datasets in order to establish whether a deviation caused by a movement exists. For example, the deviation condition can check whether a significant deviation exists that justifies separate handling.

In order to allow good comparability of the navigator datasets, an expedient development of the disclosure provides that the navigator data for all the sequence segments is acquired along an identical k-space trajectory in each case, which, in particular, includes the center of k-space. Acquiring a k-space trajectory, in particular k-space line, in the center of k-space has the advantage that most of the signal exists there, thus, a lower noise component is present, and hence, the comparison is improved further. Of course, the same radiofrequency pulse is expediently also used in all the navigator submodules in order to improve the comparability.

Exemplary aspects can provide that the navigator submodule corresponds to a readout submodule for the k-space trajectory to be sampled for the navigator data. For example, in the case of a TSE echo train, an additional TSE echo can be acquired in the navigator submodule for the k-space trajectory. It is also conceivable, however, to use another echo type or sequence type for the navigator submodule, for instance, to measure a free induction decay (FID) or a gradient echo in a TSE sequence. The latter case can also have advantages if the navigator submodule is suitably located in the readout module, which will be discussed in further detail below.

Preferably, in a first specific aspect, the navigator data can be acquired at a fixed position relative to the readout submodules, in particular before all the readout submodules or after all the readout submodules. All the navigator datasets are thereby acquired under comparable conditions, which in turn improves the comparability and simplifies determining the correlation information and, if applicable, formulating the deviation condition. For example, at the start of each readout module, in the navigator submodule can be acquired an additional echo, i.e., the navigator data, in particular from the center of k-space. The navigator submodule can also be acquired at other positions in the sequence segment, however, for example, at the end thereof.

An expedient specific aspect provides that in the case of a turbo spin echo sequence as the magnetic resonance sequence, either the navigator submodule is a gradient echo submodule after all the readout submodules, in which case the radiofrequency pulse (in this case an excitation pulse) of the navigator submodule is output having a flip angle that is reduced compared with the radiofrequency pulses of the readout submodules, and/or is output at a time interval from the preceding radiofrequency pulse (i.e. refocusing pulse) of the last readout submodule that is less than the time interval between the radiofrequency pulses of the readout submodules. Thus, in particular, this can exploit the fact that a gradient echo is not bound to the time interval of the refocusing pulses that is set in the TSE sequence. Therefore, the additional echo can be introduced with only a small increase in the acquisition time length. Alternatively, it is also conceivable that the navigator submodule is a turbo spin echo submodule in which the refocusing pulse has a smaller flip angle. In both cases, the SAR exposure can be reduced by reducing the flip angle.

In an alternative, second specific aspect, for the purpose of time-neutral implementation of the acquisition of the navigator datasets it can be provided that the navigator submodules have, at least in some cases, different positions within the readout module, covering all possible positions in the readout module, wherein the navigator data is additionally also evaluated in order to determine phase evolution information across the readout module, which is used to correct the magnetic resonance data for eddy-current effects. It is known in the prior art to provide before the first sequence segment used to acquire magnetic resonance data, in particular before the echo train in TSE imaging, an eddy-current correction sequence-segment, in particular an eddy-current correction echo-train, wherein at each position in time in the sequence segment, an echo is acquired solely at the center of k-space, wherein the phase evolution between the different echoes is determined in order to correct eddy-current effects. The determined correction is then applied in the subsequent sequence segments for acquiring magnetic resonance data. This second aspect of the present disclosure now proposes eliminating the eddy-current correction sequence-segment and instead acquiring in each sequence segment, at a different position in time, navigator data at the center of k-space. The navigator data can then both be employed as before for correcting eddy currents between the respective positions in time and be used for identifying movement-affected sequence segments.

If, in this second aspect, magnetic resonance data from an echo train is discarded, it is expedient not to use the navigator data either for the eddy-current correction. It can then be provided that for sequence segments having correlation information that satisfies the deviation condition, the phase evolution information is interpolated and/or extrapolated, while the navigator data from these sequence segments is omitted. Thus, this also avoids the movement having an influence with regard to the eddy-current effects.

At least some of the correlation information can be determined as an autocorrelation, in particular in image space. Other correlation values, in particular correlation metrics, can also be used as the correlation information, however, and also other comparison methods can be employed. For the purpose of determining the correlation, the navigator data can be transposed into image space expediently by a Fourier transform. Strongly deviating sequence segments can then be labeled for discarding or suitable weightings can be selected.

It is conceivable in principle to use a single sequence segment as a reference sequence segment and to check the level of correlation of an assessed sequence segment to the reference sequence segment. For example, the deviation condition can then check whether a correlation value relating to the navigator data of the reference sequence segment, which correlation value describes the magnitude of the correlation or deviation, for instance, as a correlation metric, is less than a threshold value. Preferably, however, the correlations between pairs of all the sequence segments (if applicable, of all those already completed) are analyzed with each other so that it is possible to avoid discarding an acquisition as a whole because the reference sequence segment was influenced by movement.

A preferred development of the disclosure provides that the correlation information comprises at least one correlation value, in particular an average correlation value for the sequence segment, wherein a reference value is determined as the mean value of the correlation values across all the sequence segments, and the deviation condition checks whether the correlation value of the sequence segment is less than a threshold value, which depends on the reference value, in particular 50 to 90% of the reference value.

In other words, it can be provided to check whether at least one correlation value deviates from the reference value (mean value) by a particular percentage threshold. It should be mentioned here that it is also possible in this case to work with just one reference sequence segment, to which the correlation value is then referred. Preferably, however, reference is made to all the sequence segments (if applicable, to all those acquired so far) so that the correlation information can comprise an average correlation value for pairs of all these sequence segments. It is thereby easy for the deviation condition to filter out sequence segments that represent outliers, whereas the (usually) greater body of similar navigator data represents sequence segments little affected by movement and can be retained, in particular with maximum weighting, for the reconstruction of a magnetic resonance image.

An expedient development of the disclosure can provide that a maximum number of magnetic resonance datasets to be discarded of individual sequence segments is used, and on being exceeded, either the acquisition process as a whole is deemed to be invalid, or the deviation condition, in particular a threshold value, is adapted in order to comply with the maximum number, and/or at least one selection criterion is used to select sequence segments, the magnetic resonance data of which is to be reintroduced for a reconstruction despite satisfying the deviation condition, in order to comply with the maximum number. The maximum number can depend on the specific acquisition process, for example, on the acceleration measures and on the options for compensating for missing magnetic resonance data in the reconstruction of magnetic resonance images, in particular in a trained reconstruction function being used. For example, the maximum number can be selected according to an acceleration factor and/or the number of sequence segments. If it is exceeded, i.e., more sequence segments than the maximum number satisfy the deviation condition, the magnetic resonance data from the acquisition process as a whole can be discarded, and in particular, a re-acquisition can be recommended. It is also possible, however, in particular after confirmation by a user, to still pursue a reconstruction. Then, the deviation condition can be adapted, for example, by raising or lowering a threshold value, or at least one selection criterion is used in order to select magnetic resonance data that has actually been discarded but is to be re-introduced nonetheless. At least one of the at least one selection criteria can relate to the magnitude of the infringement of the deviation condition. It is also particularly advantageous, however, if at least one of the at least one selection criteria relates to coverage of the k-space to be sampled, in particular, the distribution of the k-space points at which measurements were made. In a specific example, the maximum interval arising between k-space lines of the sequence segment, in particular in the echo train, can serve as the selection criterion, i.e. for echo trains that have similar deviations according to the correlation information, for which discarding the one echo train causes a maximum undersampling of four, but discarding the other echo train an undersampling of six, the choice is to retain or re-introduce the echo train with undersampling of four.

In this connection, it should also be mentioned that other fundamentally known techniques for avoiding excessive (local) undersampling can also be expediently combined synergistically with the process according to the disclosure. The process known as “Reduce Motion Sensitivity” is an example of this. For this purpose, it can be provided that a fixed assignment of k-space lines (or other k-space trajectory segments) to positions in time of readout submodules in the readout module is not made, but instead the k-space lines or k-space trajectory segments to be acquired are allocated to the readout submodules randomly or pseudo-randomly within the readout module. It is thereby possible to minimize the likelihood of large k-space gaps in regular undersampling.

In an advantageous group of exemplary aspects, the determining of the correlation information and the checking of the deviation condition can take place at least in part already during the acquisition process, in particular immediately after acquiring the navigator data and/or conclusion of the sequence segment, wherein the magnetic resonance data to be discarded of a sequence segment, for which the deviation condition is satisfied, is re-acquired at least in part in a subsequent sequence segment that has been adapted in this regard. As an alternative to, or in addition to, a judgment after the acquisition process, in particular before the reconstruction, it can therefore also be provided for the purpose of defining weights and/or magnetic resonance data to be discarded that identification of sequence segments to be discarded is carried out dynamically during the acquisition process. This makes it possible to modify the acquisition process in order to compensate for the omission and/or lessen its consequences. In particular, it can thus be provided that the sequence segment is repeated, in particular, immediately or at the end of the planned sequence segment series. In addition, the planning of the acquisition protocol can be adjusted already in view of a check of movement during the acquisition.

In this context, an expedient development provides that for a fixed or preset maximum number of sequence segments, the order of said sequence segments is specified within the acquisition protocol such that with each sequence segment, the interval between sampled k-space trajectory segments, in particular k-space lines, is reduced by a maximum in k-space. Then, if, for example, the current sequence segment, in particular the current echo train, is identified by the deviation condition as to be discarded, then the subsequent sequence segment is adapted such that it re-samples the k-space positions of the previously discarded sequence segment. Even if sequence segments would ultimately have to be omitted, this ensures that sampling of k-space is performed with minimum possible intervals so that compensating for, or estimating, missing magnetic resonance data in the reconstruction can be carried out more robustly and with higher quality.

In this context, it can also be provided expediently that the maximum number of possible sequence segments is selected to be greater than the number of sequence segments needed in movement-free sampling. For example, on activating the functionality described here, time can be reserved for spare sequence segments in order to allow, within certain limits, repetitions without loss of sequence segments. Furthermore, it is conceivable to lessen slightly the planned undersampling in order to avoid negative effects caused by overlarge sampling gaps.

Thus, it can be stated in summary and in general that increased image quality and higher insensitivity to movement, in particular also to pulsation, is achieved by the identification and discarding, or lower weighting, of defective sequence segments, in particular in combination with deep-learning reconstruction methods. In contrast with motion-correction approaches such as SAMER, the disclosure has the advantage that combining with the use of trained reconstruction functions is possible, and also, pulsation effects can be taken into account.

The present disclosure relates not only to the method but also to a magnetic resonance apparatus having a main magnet unit containing a main magnet for generating a main magnetic field, a gradient coil arrangement, a radiofrequency coil arrangement, and a control apparatus, which has:
a sequence unit for controlling an acquisition process in an acquisition process in accordance with an acquisition protocol, which comprises in at least one repetition a plurality of sequence segments of a magnetic resonance sequence, wherein each sequence segment comprises a preparation module and a readout module, and each readout module comprises a plurality of readout submodules, in which, respective radiofrequency pulses precede respective readout time periods for acquiring magnetic resonance data, wherein the sequence unit is designed to use in each readout module at least one navigator submodule for acquiring navigator data of the sequence segment;
a correlation unit for determining correlation information for each sequence segment by comparing the navigator dataset of the sequence segment with at least one navigator dataset of a further sequence segment; and
an evaluation unit for evaluating the correlation information in order to select sequence segments, the magnetic resonance data of which is to be discarded, and/or to assign a weighting to the magnetic resonance data of at least some of the sequence segments.

In particular, the evaluation unit can be designed, for example, to discard and/or to attach a lower weight to magnetic resonance data of at least one sequence segment for which at least one deviation condition, which evaluates the correlation information, is satisfied.

All the statements relating to the method according to the disclosure can be applied analogously to the magnetic resonance apparatus according to the disclosure and vice versa, and therefore, the same advantages can be achieved.

The control apparatus can comprise at least one processor and at least one storage means. Functional units for performing steps of the method according to the disclosure are formed by hardware and/or software, said functional units being, in the present case, at least a sequence unit, a correlation unit and an evaluation unit, wherein a reconstruction unit, which is fundamentally known for control apparatuses of magnetic resonance apparatuses, is therefore also provided according to the disclosure. Further functional units can also be provided, of course, in particular with regard to the various proposed aspects. For example, an adaptation unit can be present for adapting the acquisition protocol when judged during the acquisition process. The sequence unit is fundamentally equivalent to known sequence units for control apparatuses of magnetic resonance apparatuses that control the acquisition operation.

A computer program, according to the disclosure, can be loaded directly into a storage means of a control apparatus of a magnetic resonance apparatus and comprises program means such that when the computer program is executed in the control apparatus, this is induced to perform the steps of a method according to the disclosure. The computer program can be stored on an electronically readable data storage medium according to the disclosure, which therefore comprises control information stored thereon that comprises at least one computer program according to the disclosure and is configured such that when the data storage medium is used in a control apparatus of a magnetic resonance apparatus, this apparatus is designed to perform a method according to the disclosure. The data storage medium is, in particular, a non-transient data storage medium, for instance, a CD-ROM.

### DESCRIPTION OF THE DRAWINGS

Further advantages and details of the present disclosure are presented in the exemplary aspects described below and with reference to the drawings, in which:

FIG. 1 shows a flow diagram of a first exemplary aspect of the method according to the disclosure;

FIG. 2 shows an example extract from a sequence diagram of a TSE sequence in a first variant;

FIG. 3 shows an example extract from a sequence diagram of a TSE sequence in a second variant;

FIG. 4 shows a flow diagram of a second exemplary aspect of the method according to the disclosure;

FIG. 5 shows schematically a sampling diagram in the second exemplary aspect;

FIG. 6 shows a block diagram of a magnetic resonance apparatus according to the disclosure; and

FIG. 7 shows the functional design of the magnetic resonance apparatus of FIG. 6.

### DETAILED DESCRIPTION

The application of the method according to the disclosure to an acquisition process having an acquisition protocol in which a TSE is used is employed below as a specific example. A plurality of slices are acquired in a plurality of repetitions, wherein in each repetition, echo trains of a certain echo-train length of readout submodules, here TSE submodules, are used initially as sequence segments in order to acquire magnetic resonance data, in the present case a k-space line in each readout time period following a radiofrequency refocusing pulse. This example and also the use of a TSE sequence are purely by way of example.

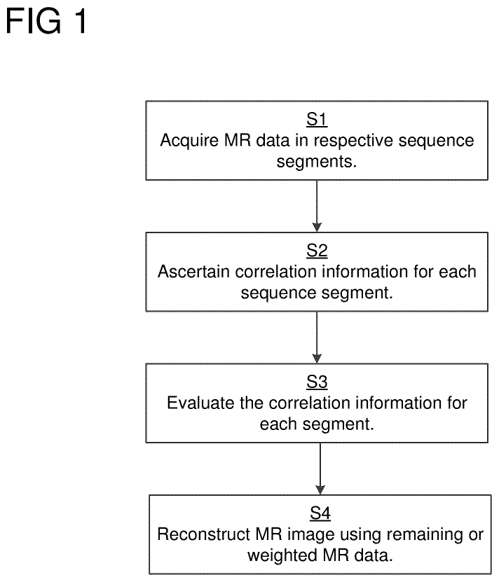

FIG. 1 shows a flow diagram of a first exemplary aspect of the method according to the disclosure. Initially, in a step S1, magnetic resonance data is acquired in the respective sequence segments, i.e., echo trains, wherein additionally in each sequence segment is used in addition to the readout submodules also a navigator submodule for acquiring navigator data. In the present exemplary aspects, the navigator submodule always samples the same acquisition trajectory in the center of k-space, in particular preferably a line or even just the center of k-space as a point. The remaining readout submodules use in the sequence segment different encodings, i.e., different k-space trajectories.

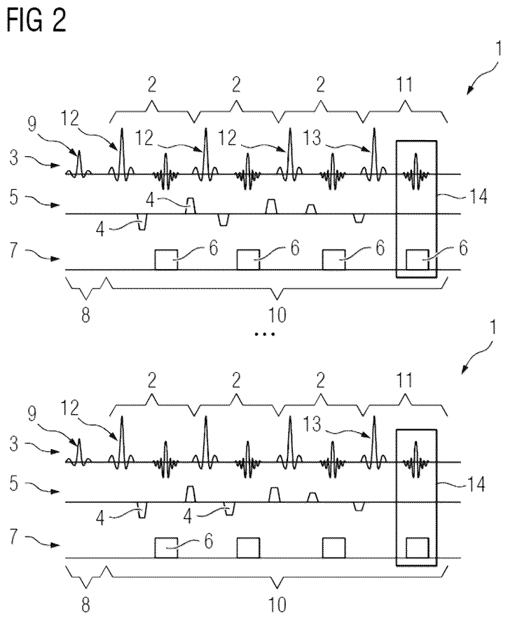

FIG. 2 shows a variant of a first aspect. For simplification, for the sequence segments 1, of which only the first and last are shown, just three readout submodules 2 in number are depicted here; in practical use, this number will be higher. In addition, the figure indicates just the radiofrequency activity in a top graph 3, the phase-encoding gradient pulses 4 in a center graph 5, and the readout time periods 6 in a bottom graph 7.

It can be seen that each sequence segment 1 comprises a preparation module 8, which in the present case is symbolized by a radiofrequency excitation pulse 9, and a readout module 10, which is subdivided into the readout modules 2 and also a navigator submodule 11. In the present case, each readout submodule 2 and the navigator submodule 11 comprise radiofrequency pulses 12, 13 that precede the respective readout time periods 6. The radiofrequency pulses 12 for the readout submodules 2, which are in the form of TSE submodules, are used for the refocusing. The navigator submodule 11 can likewise be in the form of a TSE submodule, in which case the flip angle of the radiofrequency pulse 13, likewise used for refocusing, is then chosen to be smaller. It is also conceivable, however, to select the navigator submodule 11 according to another sequence type, for instance as a gradient echo submodule, in which the radiofrequency pulse 13 can be used for exciting the gradient echo and can lie closer to the radiofrequency pulse 12 of the preceding readout submodule 2 than the intervals between the radiofrequency pulses 12.

In general, the absence of phase-encoding gradient pulses 4 for the navigator submodule 11 indicates the measurement in the center of k-space. Whatever the case, the navigator echoes 14 are acquired as navigator data so that a navigator dataset exists for each sequence segment 1.

In the aspect of FIG. 2, the position in time of the navigator submodule 11 in the readout module 10 is selected to be fixed at the end of the readout module 10. In principle, other fixed positions are also conceivable in the first aspect, for instance, at the start of the readout module 10.

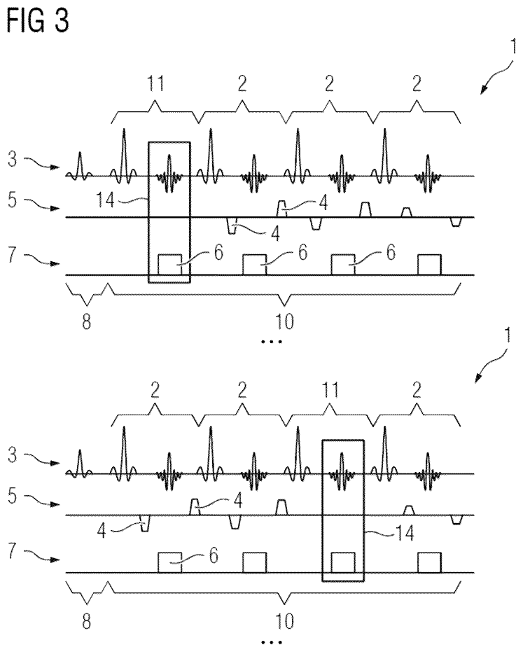

FIG. 3 illustrates schematically a second aspect, in which the position in time of the navigator submodule 11 is not fixed but varies, and varies such that all possible time positions in the readout module 10 are run through. The corresponding navigator datasets can then also be used for eddy-current correction since the phase evolution for the different positions in time can be tracked from the navigator data. It is hence possible to dispense with a separate sequence segment for the eddy-current correction navigators. Should only movement-affected navigator data be available for a position in time in the readout module 10, as will be explained later, it is possible to omit this data and to interpolate or extrapolate the eddy-current correction, the phase evolution, or the missing navigator data. In some cases, however, redundant acquisition of navigator data can be performed anyway for at least some of the positions in time, namely whenever the number of sequence segments is greater than the echo-train length.

Regardless of which aspect was actually used, in a step S2 of FIG. 1, after completion of the acquisition process, i.e., when navigator data is available for all the sequence segments 1, correlation information is ascertained for each sequence segment 1. This is done by determining for each sequence segment 1 the autocorrelation of the navigator data paired against all the other sequence segments 1. Thus, a comparison is made between the navigator data. An average correlation value is ascertained by forming the statistical mean of the individual results. In this context, a reference value can also be determined already as the mean value of all the average correlation values. In the present case, the correlation value is determined such that higher values indicate a higher correlation.

In a step S3, the correlation information is evaluated for each sequence segment 1 by a deviation condition. In the present case, the deviation condition checks whether the average correlation value of the correlation information for the particular sequence segment 1 is less than a threshold value, which is derived from the reference value as a percentage, for instance, as 50% to 90% of the reference value. If the deviation condition is satisfied, i.e., the navigator data differs significantly from the navigator data of most of the other sequence segments, movement during the sequence segment 1, which can also be a pulsation, is inferred. Since the magnetic resonance data that was acquired in the readout submodules 2 of the sequence segment 1 may also be affected by the movement, it is discarded and/or is assigned a lower weighting for a subsequent reconstruction than magnetic resonance data for sequence segments 1 for which the deviation condition is not satisfied. The weightings can expediently be selected according to the location in k-space and the magnitude of the infringement of the deviation condition, i.e., the movement magnitude. For example, the sequence segments 1 for which the deviation condition is satisfied can be sorted according to the magnitude of the infringement, and those with increasing infringement magnitude assigned a lower weighting, possibly modified by the location in k-space.

The remaining or weighted magnetic resonance data is then used in a step S4 in order to reconstruct at least one magnetic resonance image. This is done by using a trained reconstruction function, which determines from the magnetic resonance data in k-space as input data a magnetic resonance image in image space, i.e., the spatial domain, as output data. The trained reconstruction function is preferably based on an unrolled neural network architecture. Such reconstruction functions based on deep learning can compensate for the omission of magnetic resonance data particularly well and robustly, so that despite the omission of movement-affected magnetic resonance data in accordance with step S3, it is possible to reconstruct high-quality magnetic resonance images that, thanks to the omission, are unaffected or less affected by motion artifacts.

If a weighting is used, the trained reconstruction function can use as additional input data a sampling mask for the sampled k-space. Here, for lower-weighted magnetic resonance data are entered at the corresponding sample points in k-space instead of one (sampled: full weighting) or zero (not sampled: do not use) the weightings, which lie between zero and one. The weighting can be applied in the reconstruction and/or a check of the consistency between the reconstruction result and the magnetic resonance data, particularly preferably in the latter case.

It should be mentioned at this point that a maximum can also be set for the number of sequence segments for which magnetic resonance data may be discarded yet a reliable reconstruction still be possible. This maximum number can depend both on properties of the trained reconstruction function and on properties of the acquisition protocol, for example, the acceleration factor and the number of sequence segments 1. If the maximum number is exceeded in step S3, the acquisition process can be characterized as a whole as invalid because of movement, and a notice to this effect output to a user. If a reconstruction is desired nonetheless, various courses of action are conceivable. For instance, one option is to adapt the deviation condition, in the exemplary aspect in particular the threshold value, so as not to exceed the maximum number. Another option, however, is to use selection criteria in order to re-introduce magnetic resonance data of certain sequence segments 1, where, for example, besides using the magnitude of the infringement of the deviation condition as a selection criterion can be used an increase in the (if applicable local) undersampling as a result of the omission of the magnetic resonance data.

In step S3, it is also possible to dispense with a deviation condition, and all the sequence segments 1 and hence magnetic resonance data can be assigned a weighting that depends at least on the magnitude of the deviation (and hence on the movement magnitude) in the comparison, in particular described by the average correlation value. For example, the sequence segments 1 can be sorted according to the movement magnitude, and all the sequence segments 1 weighted in a, in particular linearly, decreasing manner according to movement magnitude.

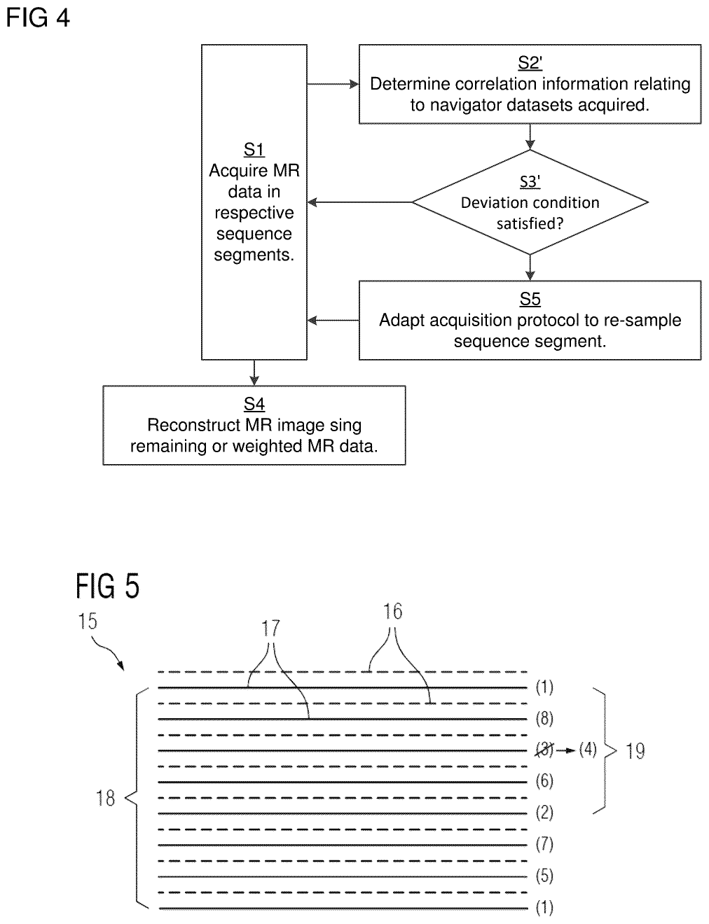

FIG. 4 shows a flow diagram of a second exemplary aspect of the method according to the disclosure. Once again, in a step S1, magnetic resonance data and navigator data are acquired in accordance with the acquisition protocol. However, while the acquisition process is still in progress, the correlation information relating to navigator datasets acquired so far is determined in a step S2′, and the check to ascertain whether the deviation condition is satisfied is performed in a step S3′. If the deviation condition is satisfied for a current sequence segment 1, the acquisition protocol can be adapted in a step S5 in order to re-acquire at least some of the discarded magnetic resonance data of the sequence segment 1, in particular to repeat the sequence segment 1. It is conceivable here to provide time in the acquisition protocol for spare sequence segments so that despite discarded magnetic resonance data in a small number of sequence segments 1, it is possible to achieve complete coverage of k-space as planned. It is also expedient, however, in particular additionally, to plan the acquisition protocol in advance so as to facilitate as good a coverage as possible with small gaps in the k-space to be acquired. In this case, the order of the sequence segments 1 can be selected in particular such that with each sequence segment 1, the maximum interval between sampled locations in k-space is reduced as much as possible.

This shall be explained in greater detail with regard to FIG. 5, which shows schematically an extract 15 from the k-space to be sampled. k-space lines 16 shown dashed are not to be sampled anyway, whereas it is intended to sample k-space lines 17 shown as continuous lines. The numbers in parentheses on the right beside the k-space lines 16, 17 indicate the sequence segment 1 for their sampling. It is evident that in the first sequence segment 1, labeled as, arises a large interval 18 in k-space, which is reduced by the maximum possible amount by the acquisition in the second sequence segment 1, labeled as; cf. interval 19. This is also planned for the third sequence segment 1, labeled (3), which, however, is discarded in step S3′ (and hence is crossed out) because the usability condition is satisfied. Therefore, in step S5, the acquisition protocol is adapted so as to re-sample in the fourth sequence segment 1, labeled (4), the k-space lines 17 of the sequence segment 1 for which the magnetic resonance data was discarded. This minimizes the gap between and as quickly as possible.

The applicable statements relating to the first exemplary aspect obviously also continue to apply to the second exemplary aspect. A combination of the exemplary aspects is also conceivable, according to which, proceeding from the second exemplary aspect, after the acquisition process, correlation information is determined again for all the sequence segments 1, and evaluated for weighting, if applicable by another or modified deviation condition or independently of same.

It should be mentioned in conclusion that the functionality described here, i.e., the identification of movement-affected sequence segments 1 and the discarding or weighting of their magnetic resonance data by means of navigator data in conjunction with a trained reconstruction function, can be activated on the magnetic resonance apparatus being used. Then, the aforementioned spare sequence segments can also be provided by the activation of the functionality. In addition, it can be expedient to reduce the undersampling slightly in order to counteract also in this manner negative effects from overlarge sampling gaps caused by discarded magnetic resonance data.

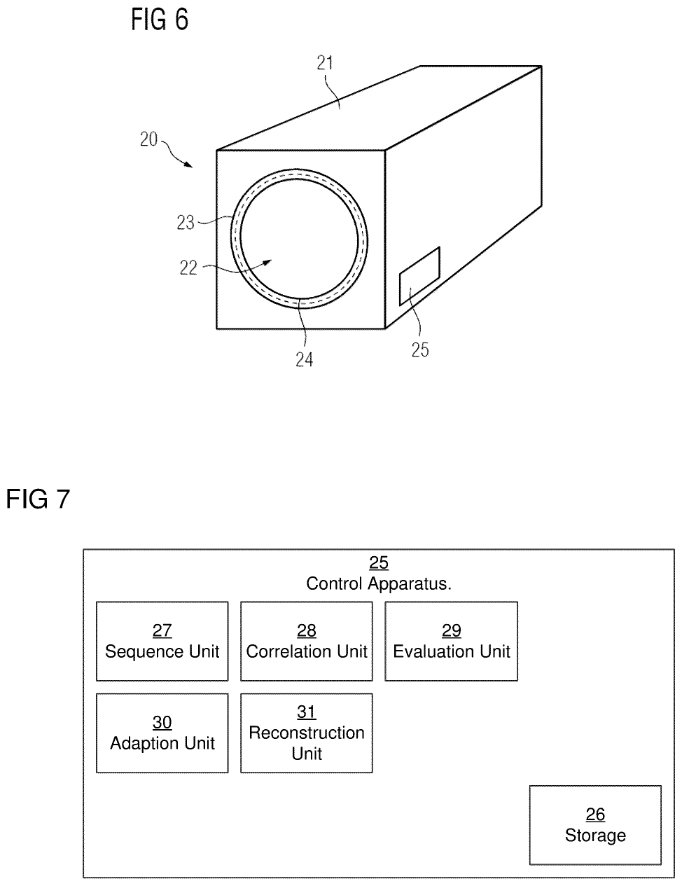

FIG. 6 shows a block diagram of a magnetic resonance apparatus 20 according to the disclosure. The magnetic resonance apparatus 20 comprises a main magnet unit 21, which contains here a superconducting main magnet (not shown in greater detail), and a cylindrical patient bore 22, into which a patient can be moved for an acquisition process using a patient couch (not shown in greater detail here). A gradient coil arrangement 23 and a reference coil arrangement 24 are provided, in the present case, surrounding the patient bore 22.

The operation of the magnetic resonance apparatus 20 is controlled by a control apparatus 25, the functional design of which is described in greater detail by FIG. 7. According to the figure, the control apparatus 25 first comprises storage means 26, in which can be stored various data, in particular also magnetic resonance data, navigator data, correlation information and the like.

The control apparatus 25 further comprises a sequence unit 27, which controls the acquisition operation of the magnetic resonance apparatus 20, in particular, using an acquisition protocol in accordance with step S1. In a correlation unit 28, correlation information can be determined in accordance with steps S2, S2′. In an evaluation unit 29, movement-affected sequence segments are then identified by evaluating the deviation condition in accordance with steps S3, S3′, and their magnetic resonance data discarded. In an adaptation unit 30, the acquisition protocol can be adapted in accordance with step S5. A reconstruction unit 31 is used for reconstructing magnetic resonance images from the (if applicable remaining) magnetic resonance data in accordance with step S4 using a trained reconstruction function, which is based in particular on an unrolled neural network architecture.

Independent of the grammatical term usage, individuals with male, female, or other gender identities are included within the term.

1. A computer-implemented method for operating a magnetic resonance apparatus in an acquisition process in accordance with an acquisition protocol, the protocol comprising, in at least one repetition, a plurality of sequence segments of a magnetic resonance sequence, wherein each sequence segment includes a preparation module and a readout module, and each readout module includes a plurality of readout submodules, each readout submodule including respective radiofrequency pulses followed by respective readout time periods during which magnetic resonance data is acquired, the computer-implemented method comprising:
acquiring a navigator dataset of the sequence segment for each readout module using at least one navigator submodule included in the readout module;
determining correlation information for each sequence segment by comparing the navigator dataset of the sequence segment with at least one navigator dataset of a further sequence segment; and
evaluating the correlation information to select sequence segments whose magnetic resonance data is discarded, and/or to assign a weighting to the magnetic resonance data of at least some of the sequence segments prior to reconstruction of a magnetic resonance image.

2. The method as claimed in claim 1, further comprising acquiring the navigator data for all the sequence segments along an identical k-space trajectory that in each case includes the center of k-space.

3. The method as claimed in claim 1, further comprising acquiring the navigator data in a fixed position relative to the readout submodules, in particular before all the readout submodules or after all the readout submodules.

4. The method as claimed in claim 3,
wherein the magnetic resonance sequence is a turbo spin echo sequence in which the radiofrequency pulses of the readout submodules are refocusing pulses,
wherein the navigator submodule is a gradient echo submodule following the readout submodules, and an excitation pulse of the navigator submodule is output having a reduced flip angle compared with the radiofrequency pulses of the readout submodules and/or is output at a time interval from a preceding radiofrequency pulse of the last readout submodule that is less than the time interval between the radiofrequency pulses of the readout submodules, or the navigator submodule is a turbo spin echo submodule in which the refocusing pulse has a smaller flip angle.

5. The method as claimed in claim 1, wherein the navigator submodules are positioned at different positions within the readout module across sequence segments, covering all possible positions in the readout module, and wherein the navigator data is additionally evaluated to determine phase evolution information across the readout module, which is used to correct the magnetic resonance data for eddy-current effects.

6. The method as claimed in claim 1, further comprising determining at least some of the correlation information as an autocorrelation.

7. The method as claimed in claim 1, wherein if at least one deviation condition, based on the correlation information, is satisfied for one of the sequence segments, the magnetic resonance data of that sequence segment is discarded or is given less weight in a subsequent reconstruction of a magnetic resonance image compared to sequence segments not satisfying the deviation condition.

8. The method as claimed in claim 7, wherein:
the correlation information comprises at least one correlation value for the sequence segment,
a reference value is determined as a mean of the correlation values across all sequence segments, and
the deviation condition checks whether the correlation value of the sequence segment is below a threshold value, which is dependent on the reference value, given a higher correlation value for stronger correlation.

9. The method as claimed in claim 7, wherein a maximum number of magnetic resonance datasets to be discarded of individual sequence segments is used, and on being exceeded, the acquisition process is deemed invalid, and/or the deviation condition is adapted to comply with the maximum number, and/or at least one selection criterion is applied to select sequence segments, the magnetic resonance data of which is to be reintroduced for a reconstruction despite satisfying the deviation condition in order to comply with the maximum number.

10. The method as claimed in claim 7, wherein the determination of correlation information and check of the deviation condition takes place at least in part during the acquisition process, and the magnetic resonance data to be discarded of a sequence segment, for which the deviation condition is satisfied, is re-acquired at least in part in a subsequent adapted sequence segment that has been adapted.

11. The method as claimed in claim 10, wherein for a fixed or preset maximum number of sequence segments, their order within the acquisition protocol is specified such that with each sequence segment, an interval between sampled k-space trajectory segments is reduced by a maximum in k-space.

12. The method as claimed in claim 1, wherein a reconstruction function that compensates for missing magnetic resonance data is used, wherein the reconstruction function is trained, receives as input data magnetic resonance data in k-space, and delivers as output data at least one magnetic resonance image in image space.

13. The method as claimed in claim 12, wherein:
the trained reconstruction function also receives a sampling mask as input data, and the sampling mask describes a distribution of sampled sample points in sampled k-space,
sample points corresponding to magnetic resonance data to be discarded are labeled as not sampled, and/or for magnetic resonance data to be weighted differently, the weighting is entered in the sampling mask at the corresponding sample points, and
the reconstruction function is configured to use the weighting in the reconstruction and/or in a consistency check between the reconstruction result and the magnetic resonance data.

14. The method as claimed in claim 1, wherein the weighting is selected according to a magnitude of a deviation of the navigator data of a sequence segment from that of the at least one further sequence segment and/or according to its location in sampled k-space.

15. The method as claimed in claim 14, wherein in order to define the weighting, a magnitude of the deviation is determined for each sequence segment, wherein the weighting decreases with the magnitude of the deviation.

16. A magnetic resonance apparatus having a main magnet unit including a main magnet configured to generate a main magnetic field, a gradient coil arrangement, a radiofrequency coil arrangement, and a control apparatus, comprising:
a sequence unit configured to control an acquisition process in accordance with an acquisition protocol, which comprises in at least one repetition a plurality of sequence segments of a magnetic resonance sequence, wherein each sequence segment comprises a preparation module and a readout module, and each readout module comprises a plurality of readout submodules, in which, respective radiofrequency pulses precede respective readout time periods for acquiring magnetic resonance data, wherein the sequence unit is configured to use in each readout module at least one navigator submodule for acquiring a navigator dataset of the sequence segment;
a correlation unit configured to determine correlation information for each sequence segment by comparing the navigator dataset of the sequence segment with at least one navigator dataset of a further sequence segment; and
an evaluation unit configured to evaluate the correlation information in order to select sequence segments, the magnetic resonance data of which is to be discarded, and/or to assign a weighting to the magnetic resonance data of at least some of the sequence segments.

17. A non-transitory electronically readable data storage medium having stored thereon a computer program such that, on execution of the computer program on a control apparatus of a magnetic resonance apparatus, performs the steps of a method as claimed in claim 1.
